(19) United States
(12) Patent Application Publication
(10) Pub. No.: US 2009/0302409 A1
(43) Pub. Date: Dec. 10, 2009

(54) IMAGE SENSOR WITH MULTIPLE THICKNESS ANTI-RELFECTIVE COATING LAYERS

(75) Inventors: Yin Qian, Milpitas, CA (US); Hsin-Chih Tai, Cupetino, CA (US); Duli Mao, Sunnyvale, CA (US); Vincent Venezia, Sunnyvale, CA (US); Hidetoshi Nozaki, Sunnyvale, CA (US); Howard E. Rhodes, San Martin, CA (US)

Correspondence Address: BLAKELY SOKOLOFF TAYLOR & ZAFMAN LLP, 1279 Oakmead Parkway, Sunnyvale, CA, 94085-4040, US

(73) Assignee: Omnivision Technologies, Inc., Sunnyvale, CA (US)

(21) Appl. No.: 12/133,299

(22) Filed: Jun. 4, 2008

(51) Int. Cl. H01L 31/00; H01L 21/00

(52) U.S. Cl. 257/437; 438/72; 257/E31.001

(57) ABSTRACT

An image sensor includes a substrate having a surface at which incident light is received. A pixel array is formed over and within the substrate. The pixel array includes a first and a second pixel arranged to receive light of different colors. The first pixel includes a photosensitive region formed in the substrate and has a first anti-reflective coating (ARC) layer formed over the photosensitive region. The first ARC layer has a first thickness that produces destructive interference above the first ARC layer in response to the incident light. The second pixel includes a photosensitive region formed in the substrate, and a second ARC layer formed over the photosensitive region that produces destructive interference above the second ARC layer in response to the incident light.

### TECHNICAL FIELD

This disclosure relates generally to imaging circuits, and in particular but not exclusively, relates to imaging sensors having antireflective coating layers.

### BACKGROUND INFORMATION

Integrated circuits have been developed to reduce the size of components used to implement circuitry. For example, integrated circuits have been using ever-smaller design features, which reduces the area used to implement the circuitry, such that design features are now well under the wavelengths of visible light. With the ever-decreasing sizes of image sensors and the individual pixels that are part of a sensing array, it is important to more efficiently capture incident light that illuminates the sensing array. Thus, more efficiently capturing incident light helps to maintain or improve the quality of electronic images captured by the sensing arrays of ever-decreasing sizes.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified.

FIG. 1 is a block diagram illustrating an image sensor, in accordance with an embodiment of the invention.

FIG. 2 is a cross-sectional view illustrating an imaging pixel of a sample imaging sensor.

FIG. 3 illustrates the deposition of a lower anti-reflective coating on a sample image sensor.

FIG. 4 illustrates the patterning of a lower anti-reflective coating on a sample image sensor.

FIG. 5 illustrates the results of etching the patterned lower anti-reflective coating on a sample image sensor.

FIG. 6 illustrates the deposition of an upper anti-reflective coating on a sample image sensor.

FIG. 7 illustrates the patterning of the upper anti-reflective coating on a sample image sensor.

FIG. 8 illustrates the results of etching the patterned upper anti-reflective coating on a sample image sensor.

### DETAILED DESCRIPTION

Embodiments of an image sensor having multiple anti-reflective coating layers are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In general, integrated circuits comprise circuitry that is employed for a variety of applications. The applications use a wide variety of devices such as logic devices, imagers (including CMOS and CCD imagers), and memory (such as DRAM and NOR- and NAND-based flash memory devices). These devices normally employ transistors for a variety of functions, including switching and amplification of signals.

Transistors are typically formed in integrated circuits by photolithographic processes that are performed on a silicon substrate. The processes include steps such as applying a photographic resist layer to the substrate, exposing the resist layer to a pattern using light (including deep ultra-violet wavelengths), removing the exposed portions (or non-exposed portions depending on the photo-positive or photo-negative resists that are used) of the resist by etching, and modifying the exposed structure, for example, by depositing or implanting additional materials to form various structure for electronic components (including transistors).

The term “substrate” includes substrates formed using semiconductors based upon silicon, silicon-germanium, germanium, gallium arsenide, and the like. The term substrate may also refer to previous process steps that have been performed upon the substrate to form regions and/or junctions in the substrate. The term substrate can also include various technologies, such as doped and undoped semiconductors, epitaxial layers of silicon, and other semiconductor structures formed upon of the substrate.

Chemical-mechanical planarization (CMP) can be performed to render the surface of the modified substrate suitable for forming additional structures. The additional structures can be added to the substrate by performing additional processing steps, such as those listed above.

As the size of the image sensors in individual pixels that are part of a sensing array become increasingly smaller, various designs attempt to more efficiently capture the incident light that illuminates the sensing array. For example, the area of the light sensing element (such as a photodiode region) of a pixel is typically maximized by arranging a microlens over (or underneath) each pixel so that the incident light is better focused onto the light sensing element. The focusing of the light by the microlens attempts to capture light that would otherwise normally be incident upon the pixel outside the area occupied by the light sensitive element (and thus lost and/or “leaked” through to other unintended pixels).

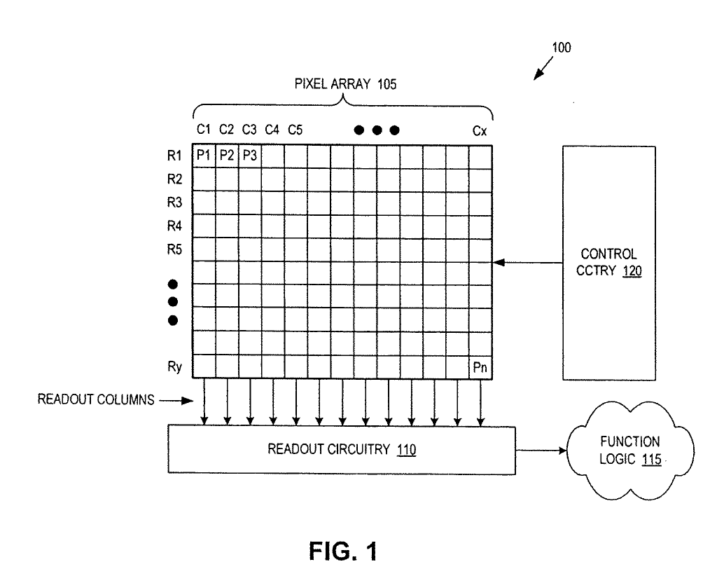

FIG. 1 is a block diagram illustrating an image sensor, in accordance with an embodiment of the invention. The illustrated embodiment of imaging sensor 100 includes a pixel array 105, readout circuitry 110, function logic 115, and control circuitry 120.

Pixel array 105 is a two-dimensional (“2D”) array of backside illuminated imaging sensors or pixels (e.g., pixels P1, P2 . . . , Pn). In one embodiment, each pixel is an active pixel sensor (“APS”), such as a complementary metal-oxide-semiconductor (“CMOS”) imaging pixel. As illustrated, each pixel is arranged into a row (e.g., rows R1 to Ry) and a column (e.g., column C1 to Cx) to acquire image data of a person, place, or object, which can then be used to render a 2D image of the person, place, or object.

After each pixel has acquired its image data or image charge, the image data is readout by readout circuitry 110 and transferred to function logic 115. Readout circuitry 110 may include amplification circuitry, analog-to-digital conversion circuitry, or otherwise. Function logic 115 may simply store the image data or even manipulate the image data by applying post image effects (e.g., crop, rotate, remove red eye, adjust brightness, adjust contrast, or otherwise). In one embodiment, readout circuitry 110 may readout a row of image data at a time along readout column lines (illustrated) or may readout the image data using a variety of other techniques (not illustrated), such as a serial readout or a full parallel readout of all pixels simultaneously.

Control circuitry 120 is coupled to pixel array 105 to control operational characteristic of pixel array 105. For example, control circuitry 120 may generate a shutter signal for controlling image acquisition.

In accordance with the present disclosure, anti-reflection coating (ARC) layers are used for image sensors. Generally, an ARC layer can be built up by using one or more film layers. By varying the thickness of the film layers, light reflection (away from a pixel photodiode) for certain colors can be reduced and more light can thus be detected by the photodiode. The ARC film thickness is optimized in accordance with a wavelength of light for which the pixel is intended to receive. Thus, different ARC film thicknesses can be chosen, for example, to optimize the detection of red, green and blue light. The ARC films can be used in both front-side and back-side illuminated sensors.

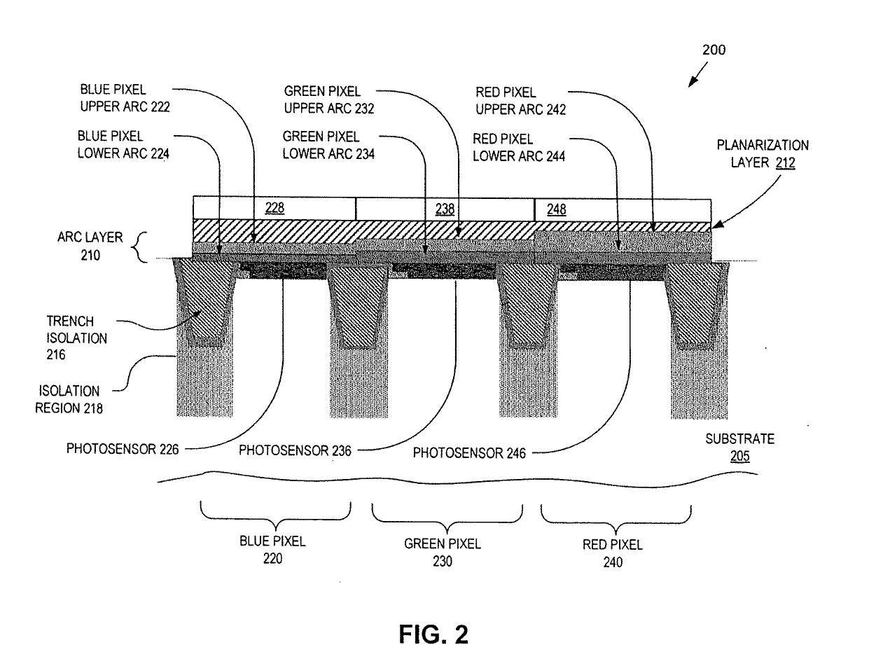

FIG. 2 is a cross-sectional view illustrating an imaging pixel of a sample imaging sensor. For simplicity, image sensor 200 is shown as including blue pixel 220, green pixel 230, and red pixel 240. Generally, image sensors include numerous pixels arranged in a bi-dimensional array as described above with reference to FIG. 1. Image sensor 200 is formed using substrate 205. The pixels are typically separated from each other using isolation regions (such as isolation region 218). Isolation region 218 may include an isolation trench (such as trench isolation 216). Each pixel typically includes a photosensitive region for capturing photonically generated electrons. For example, blue pixel 220 includes photosensor 226, green pixel 230 includes photosensor 236, and red pixel 240 includes photosensor 246.

An anti-reflective coating (ARC) layer 210 is disposed over the photosensitive region of each pixel. The ARC layer 210 can include multiple layers of coatings. For example, blue pixel 220 can include upper ARC 222 and lower ARC 224, green pixel 230 can include upper ARC 232 and lower ARC 234, and red pixel 240 can include upper ARC 242 and lower ARC 244. In an example, each upper and each lower ARC layer can be formed having an index refraction of around 2. Silicon nitride, silicon oxynitride, and the like can be used to form the ARC layers.

The anti-reflection coatings can be similar to those used on optical equipment such as camera lenses. The ARC layers can be formed by using a thin layer of dielectric material, having a thickness such that interference effects are caused. The interference effects cause a light wave reflected from the ARC top surface to be out of phase with the light wave reflected from the semiconductor surface under the ARC. Thus, the out-of-phase reflected waves destructively interfere with each another, which substantially reduces reflected energy and increases the quantum efficiency of the pixel.

The thickness of the anti-reflection coating can be chosen so that the wavelength in the dielectric material is about one quarter (and/or a fraction having an odd integer multiple of one-quarter) of the wavelength of the incoming light for a pixel. For a quarter wavelength anti-reflection coating of a transparent material with a refractive index n₁ and light incident on the coating with a free-space wavelength λ₀, the thickness d₁ which causes minimum reflection is calculated by:

$${d}_{1} = \frac{{λ}_{0}}{4 {n}_{1}} .$$

The refractive index n₁ can be chosen to further minimize reflection when the refractive index is chosen to be around the geometric mean of the indices of refraction of bordering materials: n₁=\sqrt{n₀n₂}. For example, when an ARC is used between glass (silicon dioxide) and a semiconductor (silicon), n₀=3.5 and n₂=1.5, which yields n₁=2.29.

In one example, the thickness of ARC layer 210 is calculated based on the wavelength of light for each type of pixel. For example, the ARC thickness for blue pixel 220 can be calculated using a wavelength of around 0.4 microns, which results in an ARC layer of around 0.050 microns (for an “internal” quarter wavelength of blue light) for silicon nitride (using an index of refraction of around 2). For ease of manufacture (by allowing thicker layers), the ARC layer can be an odd integer multiple of the quarter wavelength (such that destructive interference occurs). For example, a depth of five times the quarter wavelength (0.250 microns) can be used as the depth for the ARC layer for the blue pixel.

The ARC thickness for green pixel 230 can be calculated (for example) using a wavelength of around 0.53 microns, which results in an ARC layer of around 0.066 microns (for an internal quarter wavelength of green light). As mentioned above, the ARC layer can be an odd integer multiple of the quarter wavelength (such that destructive interference occurs). For example, a depth of five times the quarter wavelength (0.330 microns) can be used as the depth for the ARC layer for the green pixel.

The ARC thickness for red pixel 240 can be calculated (for example) using a wavelength of around 0.60 microns, which results in an ARC layer of around 0.075 microns (for an internal quarter wavelength of red light). As mentioned above, the ARC layer can be an odd integer multiple of the internal quarter wavelength (such that destructive interference occurs). For example, a depth of five times the quarter wavelength (0.370 microns) can be used as the depth for the ARC layer for the red pixel.

Planarization layer 212 is formed over ARC layer 210 on image sensor 200. Planarization layer 212 can be formed using silicon dioxide, which has an index of refraction of around 1.5. Planarization layer 212 provides a uniform surface across the top of image sensor 200 to which blue color filter 228, green color filter 238, and red color filter 248 can be located.

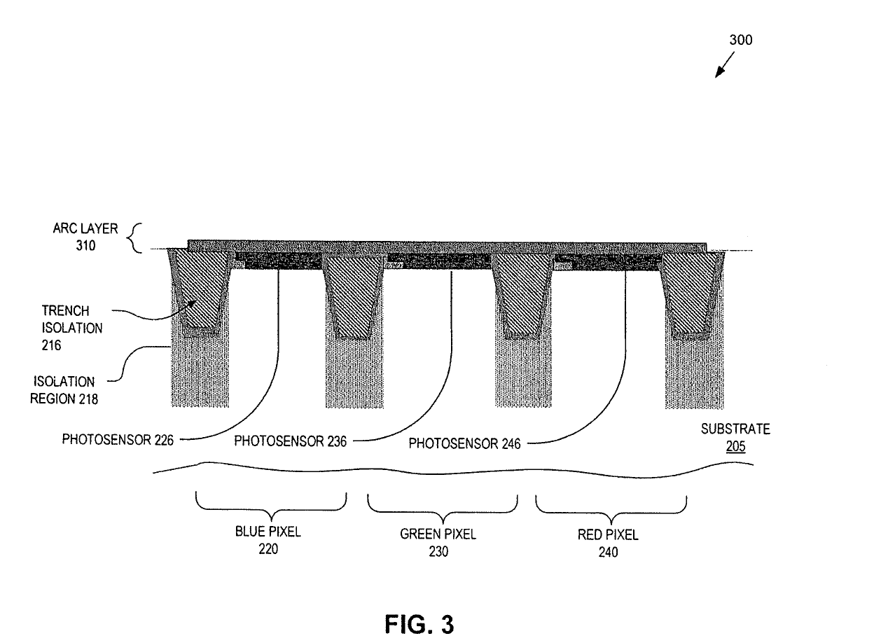

FIG. 3 illustrates the deposition of a lower anti-reflective coating on a sample image sensor 300. ARC layer 310 normally is made of SiO2, which provides low stress and low damage to underlying silicon surfaces, e.g. trench isolation 216 and photodiodes 226, 236, and 246. Since SiO2 has a lower index of refraction compared to SiN or SiON, it is usual to use a thickness of SiO2 as thin as possible, where the thickness of SiO2 is mainly limited by the process tool capabilities. However, optical simulation results indicated that for different wavelengths, the ARC layer 310 can have an optimization thickness based on different top ARC layer types, thicknesses, and indices of refraction. A thicker bottom ARC layer is normally needed for longer wavelengths of light. ARC layer 310 can be deposited to a thickness, for example, of around 0.170 microns (which is around half of the depth of the ARC layer targeted for green pixel 230 as discussed above).

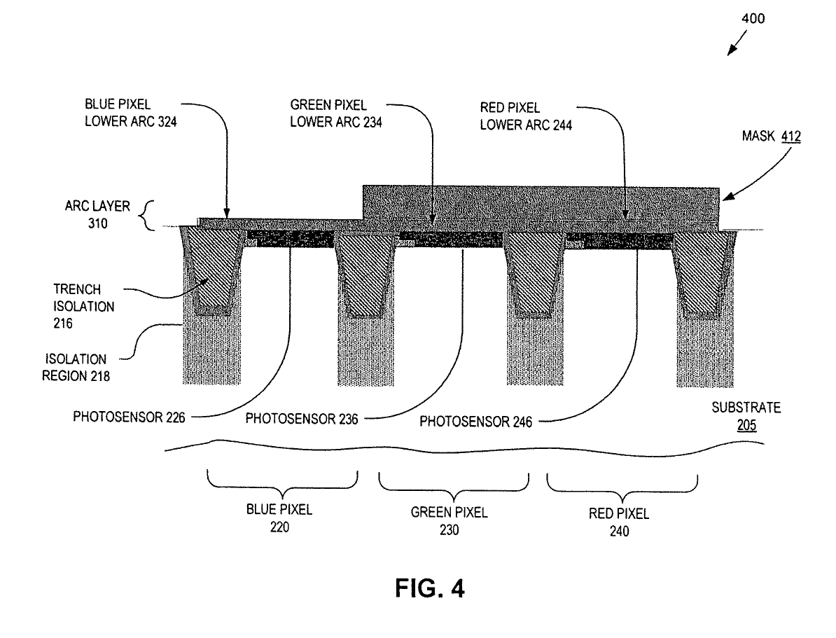

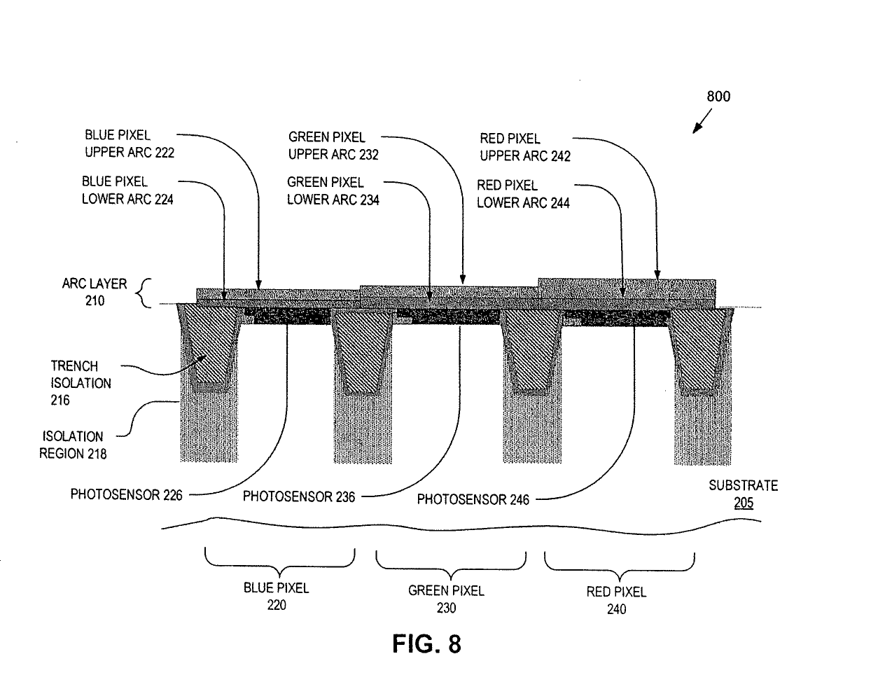

FIG. 4 illustrates the patterning of a lower anti-reflective coating on a sample image sensor 400. Mask 412 can be patterned over ARC layer 310 so that a portion of ARC layer 310 that overlies photosensor 226 can be etched (thinned) to a thickness, for example, of around 0.090 microns (which is selected in accordance with the discussion with respect to FIG. 8 below).

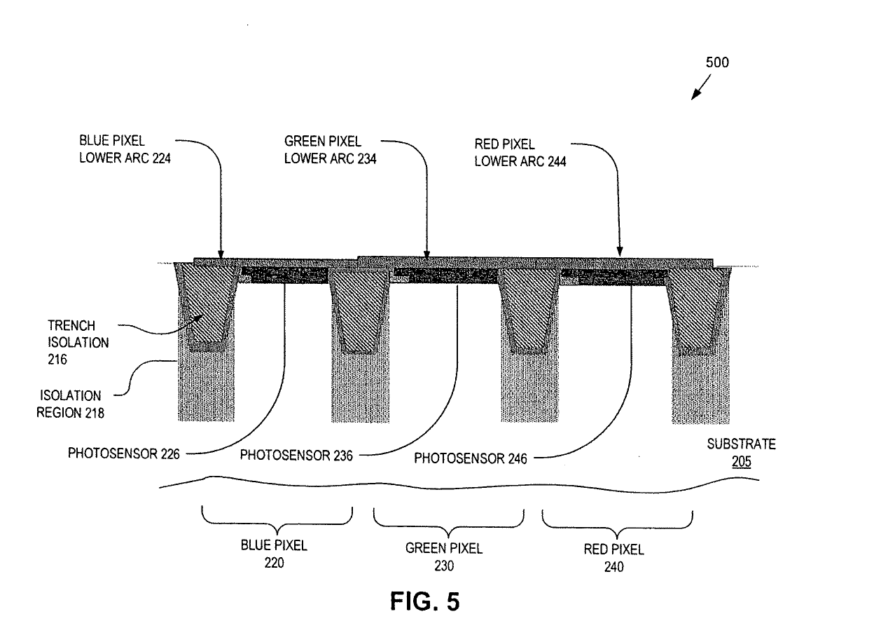

FIG. 5 illustrates the results of etching the patterned lower anti-reflective coating on a sample image sensor 500. A wet or dry etching process can be used to thin a portion of ARC layer 310 such that ARC layer 210 is formed as described above. Thus, blue pixel lower ARC 224 is thinner than green pixel lower ARC 234 and red pixel lower ARC 244. The mask 412 can be removed by a suitable etchant after the portion of the ARC layer 310 has been thinned.

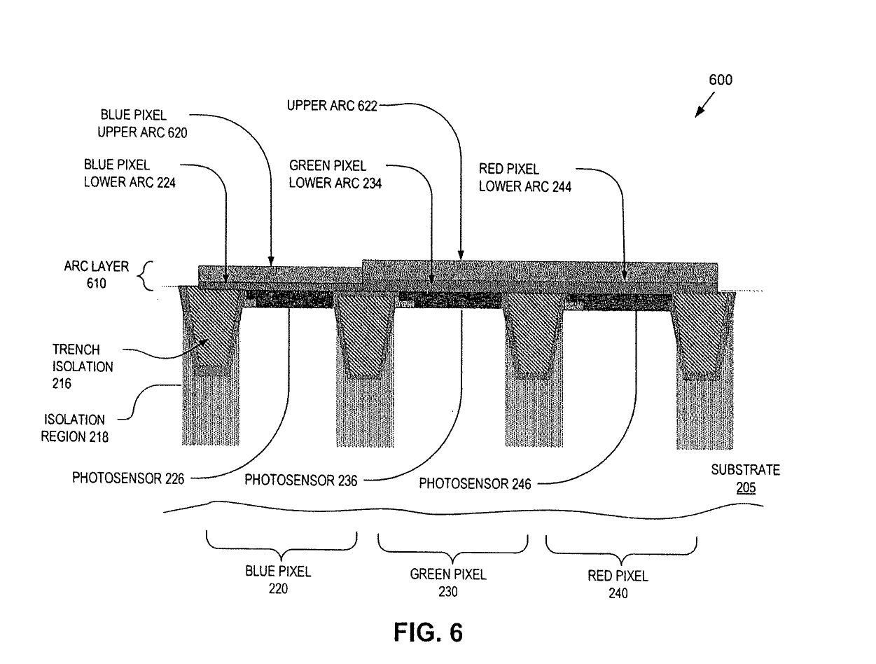

FIG. 6 illustrates the deposition of an upper anti-reflective coating on a sample image sensor 600. Upper ARC layer 622 can be made of, for example, silicon nitride (having an index of refraction of around 2). Upper ARC 622 (and blue pixel upper ARC 620) can be deposited to a thickness, for example, of around 0.200 microns (such that the total thickness of the ARC layer targeted for red pixel 240 is around 0.370 microns as discussed above). Thus the total thickness of the ARC layer 610 above green pixel 230 is 0.370 microns (0.170 microns+200 microns), which exceeds the target thickness of 0.330 microns by 0.040 microns (the excess is etched away, as described below). Also the thickness of the ARC above blue pixel 220 is 0.290 microns (0.090 microns+0.200 microns), which also exceeds the target thickness of 0.250 microns by 0.040 microns.

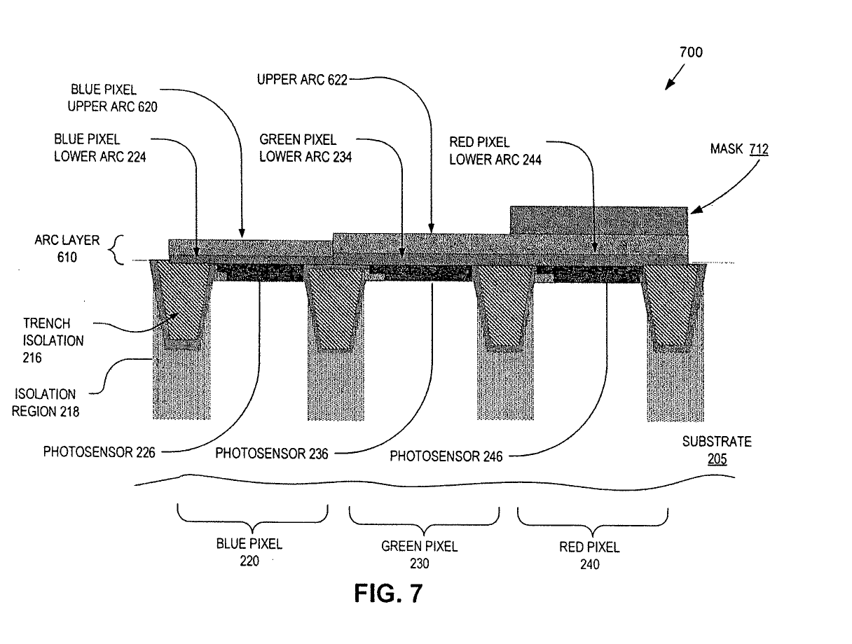

FIG. 7 illustrates the patterning of the upper anti-reflective coating on a sample image sensor 700. Mask 712 can be patterned over ARC layer 610 so that a portion of ARC layer 610 that overlies blue pixel 220 and green pixel 230 can be etched (thinned) by about, for example, 0.070 microns (such that the target thicknesses of the ARC layer for the blue pixel 220 and green 230 pixel can be achieved).

FIG. 8 illustrates the results of etching the patterned upper anti-reflective coating on a sample image sensor 800. A wet or dry etching process can be used to thin portions of ARC layer 610 by about 0.040 microns such that ARC layer 210 is formed as described above. Thus, the thickness of blue pixel upper ARC 222 (which is 0.160 microns) and the thickness of the blue pixel lower ARC 224 (which is 0.090 microns) total the targeted thickness of 0.250 microns (which is five times the internal quarter wavelength of blue light). Likewise, the thickness of green pixel upper ARC 232 (which is also 0.160 microns) and the thickness of the green pixel lower ARC 234 (which is 0.170 microns) total the targeted thickness of 0.330 microns (which is five times the internal quarter wavelength of green light). The mask 712 can be removed by a suitable etchant after the portions of the ARC layer 610 have been thinned.

Although the above description discloses an embodiment where the pixel is illuminated from the front-side (e.g., top), other embodiments are possible. For example, the ARC layer 210 as described above can be formed on the backside of an image sensor, where the image sensor is illuminated from the backside.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. An image sensor, comprising:
A first photosensor disposed in a substrate to receive incident light of a first color;
a first anti-reflective coating (ARC) layer formed over the photosensor, wherein the first ARC layer has a first thickness that produces destructive interference above the first ARC layer in response to the incident light of the first color;
a second photosensor disposed in the substrate to receive incident light of a second color; and
a second ARC layer formed over the second photosensor, wherein the second ARC layer has a second thickness that produces destructive interference above the second ARC layer in response to the incident light of the second color, wherein the first and second thicknesses are different.

2. The sensor of claim 1, further comprising a third photosensor disposed in the substrate to receive incident light of a third color, wherein the third photosensor includes a third ARC layer formed over the third photosensor, wherein the third ARC layer has a third thickness that produces destructive interference above the third ARC layer in response to the incident light of the third color, wherein the third thickness is different from the first and second thicknesses.

3. The sensor of claim 2, wherein the first thickness is around an odd multiple of an internal quarter wavelength of blue light, wherein the second thickness is around an odd multiple of an internal quarter wavelength of green light, and wherein the third thickness is around an odd multiple of an internal quarter wavelength of red light.

4. The sensor of claim 2, wherein the second pixel is adjacent to at least one of the first and third pixels.

5. The sensor of claim 2, further comprising a planarization layer above the first, second, and third ARC layers.

6. The sensor of claim 2, further comprising a blue filter above the first ARC layer, a green filter above the second ARC layer, and a red filter above the third ARC layer.

7. The sensor of claim 2, wherein the first, second, and third ARC layers each include two coatings.

8. The sensor of claim 1, wherein the first and second ARC layers comprise silicon nitride.

9. The sensor of claim 1 wherein the first and second ARC layers have an index of refraction of around 2.

10. The sensor of claim 1, wherein the incident light is received on the front side of the substrate.

11. A method, comprising:
forming a first, second, and third photosensitive region in a substrate;
forming isolation regions between the first, second, and third photosensitive regions;
depositing a first anti-reflective coating (ARC) over the first, second, and third photosensitive regions;
using a first mask to selectively etch a portion of the ARC over the first photosensitive region;
removing the first mask;
depositing a second ARC over the first ARC including the selectively etched portion of the first ARC;
using a second mask to selectively etch a portion of the second ARC over the first and second photosensitive regions; and,
removing the second mask.

12. The method of claim 11, wherein the combined thickness of the first ARC and the second ARC over the first photosensitive region is around an odd multiple of an internal quarter wavelength of blue light, wherein the combined thickness of the first ARC and the second ARC over the second photosensitive region is around an odd multiple of an internal quarter wavelength of green light, and wherein the combined thickness of the first ARC and the second ARC over the third photosensitive region is around an odd multiple of an internal quarter wavelength of red light.

13. The method of claim 12, further comprising forming a planarization layer over the second ARC.

14. The method of claim 13, further comprising forming a blue filter over the second ARC over the first photosensitive region, forming a green filter over the second ARC over the second photosensitive region, and forming a red filter over the second ARC over the third photosensitive region.

15. An image sensor, comprising:
a first pixel arranged to receive light of a first color, wherein the first pixel includes a photosensitive region formed in a substrate, a first anti-reflective coating (ARC) layer formed over the photosensitive region, wherein the first ARC layer has a first thickness that is around an odd multiple of an internal quarter wavelength of light of a first color; and
a second pixel arranged to receive light of a second color, wherein the second pixel includes a photosensitive region formed in the substrate, and a second ARC layer formed over the photosensitive region, wherein the second ARC layer has a second thickness that is around an odd multiple of an internal quarter wavelength of light of a second color that is different from the first color.

16. The imaging sensor of claim 15, further comprising a third pixel arranged to receive light of a third color, wherein the third pixel includes a photosensitive region formed in the substrate, and a third ARC layer formed over the photosensitive region, wherein the third ARC layer has a second thickness that is around an odd multiple of an internal quarter wavelength of light of a second color that is different from the first color.

17. The imaging sensor of claim 16, wherein the first pixel further comprises a blue filter, the second pixel further comprises a green filter, and the third pixel further comprises a red filter.

18. The sensor of claim 15, wherein the first ARC and the second ARC have an index of refraction of 2.

19. The imaging sensor of claim 15, wherein the first and second pixels receive light on a front side of a substrate that includes the first and second pixels.

20. The imaging sensor of claim 19, wherein the substrate comprises a bi-dimensional array of pixels.
